(19) United States
(12) Patent Application Publication
(10) Pub. No.: US 2026/0119733 A1
(43) Pub. Date: Apr. 30, 2026

(54) METHODS AND SYSTEMS FOR CALIBRATING ON-TOOL DIGITAL TWIN MODELS

(71) Applicant: Applied Materials, Inc., Santa Clara, CA (US)

(72) Inventors: Anup Doddamane, Karnataka (IN); Milan Prakash, Karnataka (IN); Girish Venkatachalapathy, Alzenau (DE); Karthik Ramanathan, Karnataka (IN)

(21) Appl. No.: 19/349,670

(22) Filed: Oct. 3, 2025

Related U.S. Application Data
(60) Provisional application No. 63/712,132, filed on Oct. 25, 2024.

(51) Int. Cl. G06F 30/17

(52) U.S. Cl. CPC G06F 30/17

(57) ABSTRACT

Methods and systems for calibrating on-tool digital twin models are provided. Process recipe data associated with a substrate process is provided as an input to an artificial intelligence (AI) model. The AI model is trained to predict simulated responses by a digital twin simulating substrate processes using simulated manufacturing equipment. Output(s) of the AI model is obtained, where the output(s) represent a predicted simulated response by the digital twin for a simulation of the substrate process using the one or more simulated manufacturing equipment based on the provided process recipe data. Data representing an actual response of the manufacturing equipment performing the substrate process based on the process recipe data is obtained. Upon a determination that a difference between the predicted response and the actual response exceeds a difference threshold, optimized values of model parameter(s) for the AI model are obtained and provided for retraining the AI model.

### CLAIM OF PRIORITY

The present application claims the benefit under 35 U.S.C. § 119(e) of U.S. Provisional Patent Application No. 63/712,132 filed Oct. 25, 2024, which is incorporated by reference herein.

### TECHNICAL FIELD

Embodiments of the present disclosure relate, in general, to manufacturing systems and more particularly to methods and systems for calibrating on-tool digital twin models.

### BACKGROUND

A digital twin of manufacturing equipment in a semiconductor manufacturing environment is a digital representation of the physical manufacturing equipment that captures the equipment's design, behavior, and real-time operational data, allowing manufacturers to simulate, monitor, and optimize processes that use the manufacturing equipment.

### SUMMARY

Some of the embodiments described cover a system and method calibrating on-tool digital twin models. The method includes providing, as an input to an artificial intelligence (AI) model, process recipe data associated with a substrate process. The AI model is trained to predict simulated responses by a digital twin simulating substrate processes using one or more simulated manufacturing equipment. The method further includes obtaining one or more outputs of the AI model. The one or more outputs represent a predicted simulated response by the digital twin for a simulation of the substrate process using the one or more simulated manufacturing equipment based on the provided process recipe data. The method further includes obtaining data representing an actual response of one or more manufacturing equipment performing the substrate process based on the process recipe data. The method further includes responsive to determining that a difference between the predicted simulated response and the actual response exceeds a difference threshold, obtaining optimized values of one or more model parameters for the AI model. The optimized values of the one or more model parameters cause the difference between the predicted simulated response and the actual response to fall below the difference threshold. The method further includes providing the optimized values of the one or more model parameters for retraining the AI model.

In some implementations, the method further includes responsive to determining that one or more retraining criteria associated with the AI model are satisfied, providing the retrained AI model to a computing device associated with a manufacturing system that includes the one or more manufacturing equipment.

In some implementations, the method further includes providing the one or more outputs of the AI model indicating the predicted simulated response and the obtained data representing the actual response as an input to an optimization engine. The optimization engine performs one or more operations to determine an optimization function associated with the AI model, and identify the optimized values of the one or more model parameters based on sampling data provided as input to the determined optimization function. The optimized values of the one or more model parameters are obtained based on one or more outputs of the optimization engine.

In some implementations, the optimization engine includes a Bayesian optimization model, and the optimization function includes a cost function.

In some implementations the predicted simulated response includes at least one of a predicted simulated condition of the one or more simulated manufacturing equipment based on the simulation of the substrate process, or a predicted simulated characteristics of one or more simulated substrates subject to the simulated substrate process, and the actual response includes at least one of an actual condition of the one or more manufacturing equipment performing the substrate process based on sensor data collected by one or more sensors of the one or more manufacturing equipment, or actual characteristics of one or more substrates subject to the substrate processed performed using the one or more manufacturing equipment based on metrology data collected for the one or more substrates.

In some implementations, providing the optimized model parameters for retraining the AI model includes identifying one or more hyperparameters of the AI model corresponding to the model parameters associated with the optimized values, and updating current values of the identified one or more hyperparameters to match the optimized values.

In some implementations, the AI model is trained using a training data set including one or more training inputs and, for each of the one or more training inputs, a target output. A training input includes process recipe data associated with a historical substrate process performed using one or more additional manufacturing equipment and the target output includes the actual response of the one or more additional manufacturing equipment based on a performance of the historical substrate process according to a process recipe of the process recipe data.

In some implementations, the AI model is a Gaussian Process regression model.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts an illustrative system architecture, according to aspects of the present disclosure.

FIG. 2 is a block diagram of an example calibration engine, according to aspects of the present disclosure.

FIG. 3 is block diagram depicting an example of calibrating an on-tool digital twin model, according to aspects of the present disclosure.

FIG. 4 is a flow chart of an example method for calibrating on-tool digital twin models, according to aspects of the present disclosure.

FIG. 5 is a flow chart of another example method for calibrating on-tool digital twin models, according to aspects of the present disclosure.

FIG. 6 depicts a block diagram of an illustrative computer system operating in accordance with one or more aspects of the present disclosure.

### DETAILED DESCRIPTION OF EMBODIMENTS

Implementations described herein provide methods and systems for calibrating on-tool digital twin models. A digital twin refers to a highly detailed virtual model or replica of one or more manufacturing equipment of a manufacturing environment. A digital twin can be created based on historical data collected based on processes performed using the one or more manufacturing equipment (e.g., in the physical world). For example, as a process is performed using the one or more manufacturing equipment, data associated with the environment within the manufacturing equipment and/or the conditions of objects (e.g., substrates) subject to such processes is continuously collected and provided to update the digital twin to match the simulations performed by the digital twin to physical world. Process data for future processes can be provided to the digital twin, which can generate simulation data representing a simulated response of the one or more manufacturing equipment based on the given process data.

Simulation data generated by a digital twin can encompass a wide range of process parameters, which can offer insight into the sensitivity of process outputs based on given process inputs. In semiconductor manufacturing, digital twins are used to simulate highly complex applications, the outputs of which, in some instances, can be highly sensitive to variations among manufacturing equipment. Calibrating and/or tuning a digital twin based on specific manufacturing equipment characteristics can be a difficult and time-consuming process. For example, a system may calibrate a digital twin for a specific manufacturing equipment by selecting initial design on experiment (DOE) parameter values, providing the initial DOE parameter values as an input to the digital twin, obtaining one or more outputs of the digital twin, determining whether a simulated response of the one or more outputs match an actual response of the manufacturing equipment subject to the DOE parameter values. If the simulated response does not match the actual response of the manufacturing equipment, the system can continue this process based on updated DOE parameter values (e.g., until the simulated response by the digital twin matches the actual response of the manufacturing equipment). Upon determining the DOE parameter values that cause the simulated response to match the actual response, the system can update the digital twin based on the determined DOE parameter values.

As indicated above, calibrating a digital twin can involve executing the digital twin using different DOE parameter values, which can take a significant amount of time. For example, identifying DOE parameter values for calibrating the digital twin can involve multiple initial guesses and can sometimes warrant expert intervention (e.g., by a human expert for the manufacturing system and/or the process). Further, users of a digital twin (e.g., developers or operators in a manufacturing environment) may change a process and/or manufacturing equipment for which a digital twin has been calibrated, which may involve re-calibrating the digital twin prior to implementing such changes. As indicated above, it can take a significant amount of time for the system to identify DOE parameter values for calibrating the digital twin, performing operations to obtain simulated responses of the digital twin based on the identified DOE parameter values, and, once parameter values that cause a simulated response to match an actual response to are identified, update the digital twin based on such parameter values. During such calibration process, a significant amount of computing resources (e.g., processing cycles, memory space, etc.) of the system are consumed, which makes such computing resources unavailable to other processes of the system, therefore decreasing an overall efficiency and increasing an overall latency of the system.

Finally, some systems may implement critical applications in the manufacturing environment based on predictions or simulation outputs of the digital twin (e.g., advanced process control, recipe management, chamber matching, predictive maintenance, etc.). Such applications can be highly dependent on conditions of the specific manufacturing environment for which processes are being performed. Even if calibration data reflecting the conditions of the specific manufacturing environment is available to a system, it can take such system a significant amount of time to calibrate the digital twin to accurately (or semi-accurately) model the specific manufacturing environment, which, in some instances, can violate time constraints associated with such applications.

Aspects of the present disclosure address the above noted and other deficiencies by providing methods and systems for calibrating on-tool digital twin models based on data that is specific for a particular manufacturing environment. In some embodiments, a system can obtain an on-tool digital twin model (also referred to as a surrogate model) that is trained to predict a simulated response of a digital twin representing a simulated substrate process. In some instances, the digital twin may be trained or otherwise developed to provide a simulated response of a simulated substrate process based on test data or experimental data for manufacturing equipment located in multiple different manufacturing environments. For example, the digital twin may be trained or developed to provide the simulated response based on test data or experimental data for target (or “golden”) conditions of manufacturing equipment across the different manufacturing environments. In another example, the digital twin may be trained or developed to provide the simulated response based on actual data collected for multiple processes (e.g., hundreds, thousands, etc.) performed using multiple different pieces of manufacturing equipment across different manufacturing environments. The digital twin may provide the simulated response based on given DOE inputs, which can vary process conditions and/or hyper parameters, in some embodiments.

The surrogate model of the present disclosure can be built or otherwise trained based on simulated data that is specific to a particular manufacturing environment for which an actual substrate process is to be performed. For example, the system can train the surrogate model by providing one or more parameter values associated with an actual historical process performed using physical manufacturing equipment of the particular manufacturing environment as an input to the digital twin and obtaining one or more outputs of the digital twin. The parameter values associated with the actual historical process can include an actual response of equipment in the manufacturing environment e.g., as reflected by sensor or metrology data collected for the historical process. The one or more outputs of the digital twin can represent a simulated response of the simulated manufacturing equipment based on the simulated substrate process. The system can generate training data including a training input and a target output, where the training input includes the one or more parameter values provided as the input to the digital twin and the target output includes the simulated response of the one or more outputs of the digital twin. The system can update a training data set for training the surrogate model to include the generated training data and can provide the updated training data set for training the surrogate model (e.g., upon determining that one or more training data criteria are satisfied).

Upon training the surrogate model, the system can obtain data representing an actual response of one or more manufacturing equipment performing the substrate process (e.g., in the physical world). The obtained data can include sensor data that is collected by one or more sensors of the manufacturing equipment (e.g., prior to, during, or after performance of the substrate process), in some embodiments. In other or similar embodiments, the obtained data can include metrology data that represents a condition of a substrate (or set of substrates) processed according to the substrate process. The system can provide one or more parameter values associated with the substrate process as an input to the trained surrogate model and can obtain one or more outputs, indicating the predicted simulated response of the digital twin. The system can determine whether a difference between the actual response of the manufacturing equipment and the predicted simulated response of the output(s) of the AI model falls below a threshold difference. If not, the system can obtain one or more optimized model parameter values which cause the difference to fall below the difference threshold. In some embodiments, the system can obtain the one or more optimized model parameter values by providing the one or more outputs representing the predicted simulated response and the obtained data representing the actual response as an input to an optimization engine and obtaining one or more outputs of the optimization engine. The optimization engine can perform one or more operations to determine an optimization function associated with the AI model and identify the optimized model parameters based on sampling data provided as input to the determined optimization function. In some embodiments, the optimized model parameter values can include or otherwise correspond to process conditions and/or hyperparameter values that, when applied to the surrogate model, will cause the output of the surrogate model to match (or approximately match) the actual equipment response.

Upon obtaining the optimized model parameter values, the system can provide the optimized model parameter values to retrain the surrogate model. The retrained surrogate model can represent a digital twin of the specific manufacturing equipment performing the substrate process. In some instances, the system can provide the retrained surrogate model to one or more computing devices associated with a manufacturing system including the manufacturing equipment. The computing devices can use the surrogate model to identify optimized process parameter values and/or settings to be applied to such manufacturing equipment to obtain a target process result associated with the substrate process.

As described herein, the difference between the surrogate model response and the actual response can be minimized using a cost function by a global optimizer. The global optimizer can determine one or more parameter values to match the actual equipment response. The determined one or more parameter values can be fed back to the digital twin to validate the surrogate model response. If the difference between the surrogate model response and the digital twin response is above a threshold difference, this response is used as an additional datapoint to retrain the surrogate model. The above described operations can be repeated until the difference between the surrogate model response and the digital twin response is below the threshold difference or until a computation budget (e.g., max iterations based on the time constraint) is reached. At such instance, the parameter values can be used to tune the digital twin that is used for the actual equipment/process.

Aspects of the present disclosure address deficiencies of the conventional technology by providing a system of a manufacturing environment with access to an on-tool digital twin model that is trained and calibrated based on data that is specific to the manufacturing environment. As indicated above, model parameters of the on-tool digital twin model are calibrated based on a difference between initial simulation responses associated with outputs of the model (e.g., obtained after training and prior to calibration of the model) and actual responses of a physical process performed using manufacturing equipment of the manufacturing system. Accordingly, the trained on-tool digital twin model can represent the digital twin of the specific manufacturing equipment performing the physical process based on the actual conditions of the physical process and/or the specific manufacturing equipment. Such trained on-tool digital twin model can be based on (or can otherwise include) a model type that is significantly less complex and consumes fewer computing resources (e.g., processing cycles, memory space, etc.) than a physics-based digital twin model, which enables the system to access simulated data associated with a specific manufacturing environment without retraining and recalibrating the physics-based digital twin model and/or running the simulation using the physics-based digital twin model. Therefore, the amount of time for training, inference, and calibration of the on-tool digital twin model is significantly reduced, which conserves a significant amount of computing resources. Such computing resources can be used for other processes of the system, which improves the overall efficiency and decreases the overall latency of the system.

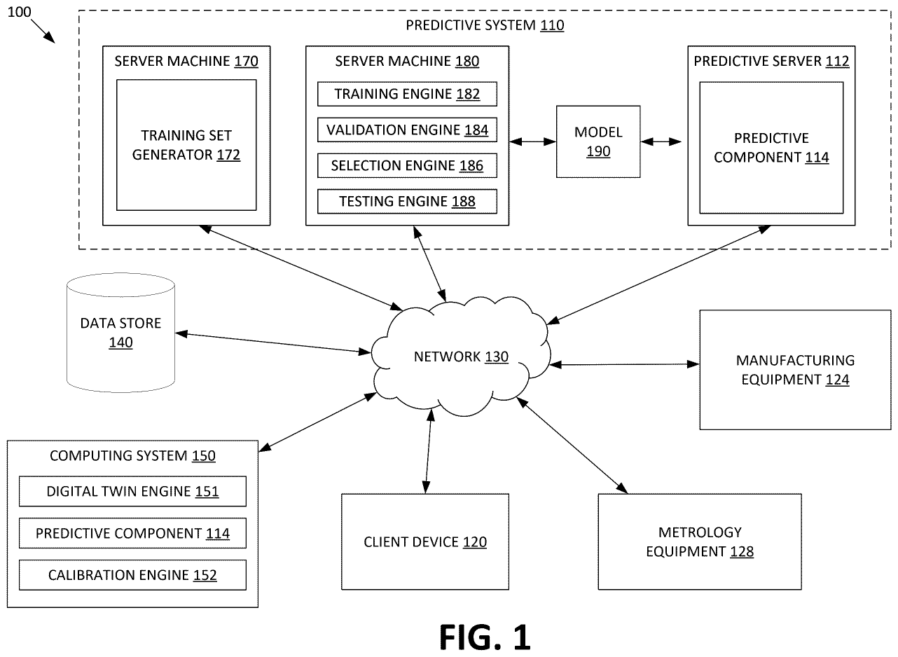

FIG. 1 depicts an illustrative system architecture 100, according to aspects of the present disclosure. System architecture 100 can include a client device 120, manufacturing equipment 124, metrology equipment 128, a predictive server 112 (e.g., to generate predictive data, to provide model adaptation, to use a knowledge base, etc.), and/or a data store 140. The predictive server 112 can be part of a predictive system 110. The predictive system 110 can further include server machines 170 and 180. In some embodiments, system architecture 100 can be included as part of or otherwise connected to a manufacturing system for processing substrates.

Manufacturing equipment 124 can produce products, such as electronic devices, following a recipe or performing runs over a period of time. Manufacturing equipment 124 can include a process chamber. Manufacturing equipment 124 can perform a process for a substrate (e.g., a wafer, etc.) at the process chamber. Examples of substrate processes include a deposition process to deposit a film on a surface of the substrate, an etch process to form a pattern on the surface of the substrate, a polishing process to polish a material on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc. Substrates that are processed according to a process recipe (e.g., for manufacturing a portion of an electronic device, etc.) are referred to herein as production substrates.

Manufacturing equipment 124 can include one or more sensors 126 configured to capture data for a substrate being processed at the manufacturing system. In some embodiments, the manufacturing equipment 124 and sensors 126 can be part of a sensor system that includes a sensor server (e.g., field service server (FSS) at a manufacturing facility) and sensor identifier reader (e.g., front opening unified pod (FOUP) radio frequency identification (RFID) reader for sensor system). Sensor data may include a value of one or more of temperature (e.g., heater temperature), spacing (SP), pressure, high frequency radio frequency (HFRF), RF bias, voltage of electrostatic chuck (ESC), electrical current, flow, power, voltage, etc. Sensor data may be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data 142 can be different for each substrate. In some embodiments, sensor data can include trace data collected during performance of one or more processes (e.g., substrate processes, maintenance processes, etc.) at manufacturing equipment 124. Trace data refers to data that indicates how components in a process chamber are operating and/or a state of an environment within a process chamber before, during, or after performance of an operation. Further details regarding sensor data are provided herein.

Metrology equipment 128 provides metrology data associated with substrates (e.g., production substrates, seasoning substrates, etc.) processed by manufacturing equipment 124. The metrology data can include a value of one or more of film property data (e.g., wafer spatial film properties), dimensions (e.g., thickness, height, etc.), dielectric constant, dopant concentration, density, defects, etc. In some embodiments, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology equipment 128 can be configured to generate metrology data associated with a substrate before or after a substrate process and/or a maintenance process. In some embodiments, metrology equipment 128 can be part of a metrology system that includes a metrology server (e.g., a metrology database, metrology folders, etc.) and metrology identifier reader (e.g., FOUP RFID reader for metrology system).

Metrology equipment 128 can be integrated with a station of the process tool of manufacturing equipment 124. In some embodiments, metrology equipment 128 can be coupled to or be a part of a station of the process tool that is maintained under a vacuum environment (e.g., a process chamber, a transfer chamber, etc.). Such metrology equipment 128 is referred to as integrated metrology equipment. Accordingly, the substrate can be measured by the integrated metrology equipment while the substrate is in the vacuum environment. For example, after a process (e.g., an etch process, a deposition process, etc.) is performed for the substrate, the metrology data for the substrate can be generated by the integrated metrology equipment without the processed substrate being removed from the vacuum environment. In other or similar embodiments, metrology equipment 128 can be coupled to or be a part of the process tool station that is not maintained under a vacuum environment (e.g., a factory interface module, etc.). Such metrology equipment is referred to as inline metrology equipment. Accordingly, the substrate is measured by the inline metrology equipment outside of the vacuum environment.

In additional or alternative embodiments, metrology equipment 128 can include metrology measurement devices that are separate (i.e., external) from manufacturing equipment 124. For example, metrology equipment 128 can be standalone equipment that is not coupled to any station of manufacturing equipment 124. For a measurement to be obtained for a substrate using external metrology equipment, a user of a manufacturing system (e.g., an engineer, an operator) can cause a substrate processed at manufacturing equipment 124 to be removed from manufacturing equipment 124 and transferred to metrology equipment 128 for measurement. In some embodiments, metrology equipment 128 can transfer metrology data generated for the substrate to the client device 120 coupled to metrology equipment 128 via network 130 (e.g., for presentation to a manufacturing user, such as an operator or an engineer). In other or similar embodiments, the manufacturing system user can obtain metrology data for the substrate from metrology equipment 128 and can provide the metrology data to computer system architecture via a graphical user interface (GUI) of client device 120.

The client device 120 my include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some embodiments, the metrology data may be received from the client device 120. In some embodiments, client device 120 displays a graphical user interface (GUI), where the GUI enables the user to provide, as input, metrology measurement values for substrates processed at the manufacturing system. In other or similar embodiments, client device 120 can display another GUI that enables user to provide, as input, an indication of a type of substrate to be processed at the manufacturing system, a type of process to be performed for the substrate, and/or a type of equipment at the manufacturing system. In yet other or similar embodiments, client device 120 can display another GUI that presents sensor data collected by sensors 126 before, during, or after performance of a process (e.g., a substrate process, a maintenance process, etc.). It should be noted that one or more GUIs of client device 120 can provide and/or receive any data described herein.

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by sensors 126 at manufacturing equipment 124 before, during, or after a substrate process (referred to as process data). Process data can refer to historical process data (e.g., process data generated for a previous substrate processed at the manufacturing system) and/or current process data (e.g., process data generated for a current substrate processed at the manufacturing system). Current process data can be data for which predictive data is generated. In some embodiments, data store can store metrology data including historical metrology data (e.g., metrology measurement values for a prior substrate processed at the manufacturing system). The data store 140 can also store contextual data associated with one or more substrates processed at the manufacturing system. Contextual data can include a recipe name, recipe operation number, preventive maintenance indicator, operator, etc. In some embodiments, contextual data can also include an indication of a difference between two or more process recipes or process operations.

In some embodiments, data store 140 can be configured to store data that is not accessible to a user of the manufacturing system. For example, process data, spectral data, non-spectral data, and/or positional data obtained for a substrate being processed at the manufacturing system may not be accessible to a user of the manufacturing system. In some embodiments, all data stored at data store 140 is inaccessible by a user (e.g., an operator) of the manufacturing system. In other or similar embodiments, a portion of data stored at data store 140 is inaccessible by the user while another portion of data stored at data store 140 is accessible by the user. In some embodiments, one or more portions of data stored at data store 140 are encrypted using an encryption mechanism that is unknown to the user (e.g., data is encrypted using a private encryption key). In other or similar embodiments, data store 140 includes multiple data stores where data that is inaccessible to the user is stored in one or more first data stores and data that is accessible to the user is stored in one or more second data stores.

Computing system 150 can include a digital twin engine 151 that performs simulations for processes using manufacturing equipment 124 based on a digital twin of manufacturing equipment 124. A digital twin refers to a virtual representation of manufacturing equipment 124 that models the design, behavior, and real-time operational data associated with an actual process (e.g., a substrate process) performed using manufacturing equipment 124. In some embodiments, the digital twin can represent a processing chamber and can simulate a substrate process performed using the processing chamber. However, it should be noted that the digital twin can represent any type of manufacturing equipment 124, in accordance with embodiments described herein. The digital twin may utilize principles and/or equations related to heat transfer, energy balance, and/or fluid dynamics to model behavior of a processing chamber during performance of a substrate process according to a process recipe. Based on a simulation of a substrate process by the digital twin, the digital twin can provide one or more simulation outputs, which can include characteristics of an environment in the simulated manufacturing equipment during the simulated process (e.g., a temperature of the simulated equipment, a pressure of the simulated equipment, a composition and/or concentration of one or more chemicals in the simulated equipment, etc.), characteristics of one or more simulated objects in the simulated equipment before, during, and/or after the simulated process (e.g., material characteristics, electrical characteristics, optical characteristics, etc.), and so forth.

In some embodiments, the digital twin can be built or otherwise obtained based on a complex, multi-step process that combines physics-based modeling, machine learning, real-time data integration, and process simulation. For example, digital twin engine 151 can identify one or more data stores that store data associated with actual processes performed using physical equipment (e.g., manufacturing equipment 124 and/or other equipment of system 100 or of another system). The data stores can include, for example, sensor data collected by one or more sensors (e.g., a pressure sensor, a temperature sensor, a gas flow sensor, etc.) before, during, or after the actual process, process recipe data (e.g., values of one or more settings of a process recipe for the actual process), equipment data (e.g., an equipment configuration, physical characteristics of components of the equipment, such as a geometry, materials, wear states, etc.), metrology data associated with one or more substrates subject to the actual processes (e.g., collected by metrology equipment 128 and/or other metrology equipment of system 100 or another system), and other data related to the actual process (e.g., environmental conditions within the equipment, etc.). The data of the identified data stores may be collected based on actual processes performed using a large number of equipment (e.g., hundreds, thousands, etc.). Digital twin engine 151 can build one or more simulation models for the manufacturing equipment using data of the identified data stores and one or more physical models that simulate the underlying physical and chemical processes occurring in the chamber. Such physical models can include, but are not limited to, fluid dynamics models (e.g., which simulate gas flows, pressure distributions, etc.), thermal models (e.g., which simulate heat transfer, temperature distributions, thermal cycling effects, etc.), plasma models (e.g., which simulate plasma generation and/or interactions in processes, etc.), chemical reaction models (e.g., which model the process based on reaction kinetics), and so forth.

In addition, digital twin engine 151 can train one or more AI-based models that are executed with the physics-based models to capture patterns, anomalies, or trends associated with the processes that are simulated by the digital twin. The models can include predictive models (e.g., that predict key outcomes such as deposition thickness, etch rates, etc. based on sensor data and input parameters), anomaly detection models (e.g., that detect abnormal chamber conditions indicating potential faults, drifts, or out-of-spec processing), and/or hybrid models (e.g., models that combine AI-based models and physics-based models to capture nuances that are difficult to model physically).

In some embodiments, digital twin engine 151 can run a simulation of a substrate process by providing data associated with the substrate process as an input to the digital twin and obtaining one or more outputs of the digital twin. The data associated with the substrate process can include, for example, process parameters (e.g., temperature, gas flows, pressure, plasma power, etc.), process recipe data (e.g., timing, chemical mixtures, gas flow sequences, etc.), material properties (e.g., substrate materials, gas types, chamber coating materials, etc.), and so forth. The digital twin can execute the physical models based on the input data and/or can apply the AI-based models to the input data. In some embodiments, DOE inputs can be provided to the digital twin, which may vary both process conditions and hyperparameters. An output of the physical models and/or the AI-based models can include an indication of a simulated response of the simulated process using the digital twin. The simulation response can include, in some embodiments, an outcome of the simulated process (e.g., a film thickness, deposition rate, etch rate, etch profile, film uniformity, defect density, particle contamination, etc.) and/or one or more conditions of the environment of the simulated equipment before, during, and/or after the simulated process.

In additional or alternative embodiments, digital twin engine 151 can train and/or implement one or more AI models 190 that can be used as a surrogate of the digital twin (referred to herein as a surrogate model 190). A surrogate model 190 refers to an AI model that represents a simplified, approximated version of the full digital twin and is designed to be faster and less computationally demanding than the digital twin. Digital twin engine 151 can perform one or more operations to initiate a training process by predictive system 110 to train the surrogate model 190, as described below.

In some embodiments, predictive system 110 includes server machine 170 and server machine 180. Server machine 170 includes a training set generator 172 that is capable of generating training data sets (e.g., a set of training inputs and a set of target outputs) to train, validate, and/or test a machine learning model 190. A training input of a training data set can include process data (e.g., process recipe data, equipment condition data, etc.) associated with an actual process performed using equipment 124 (or other equipment) and a target output for the training input can include a simulated response of a simulation performed by the digital twin using the process data. In some embodiments, training set generator 172 can initialize a training set T to an empty set (e.g., {}) and can identify process data associated with an actual process performed using manufacturing equipment 124 (e.g., of data store 140). Training set generator 172 can additionally or alternatively obtain a simulated response of a simulation performed by the digital twin using the process data. For example, training set generator 172 (or a component of digital twin engine 151) can provide the process data as an input to the digital twin and can obtain one or more outputs of the digital twin, which can indicate the simulated response. In other or similar embodiments, training set generator 172 can identify the simulated response from data store 140 (e.g., obtained based on a prior simulation performed using the digital twin based on the process data). Training set generator 172 can generate a training input based on the identified process data and a target output based on the obtained simulation response data and, in some embodiments, can generate a mapping between the training input and target output. Training set generator 172 can add the mapping to the training set T and, upon determining that one or more training criteria are satisfied (e.g., the training set T includes a threshold number of mappings, etc.) provide the training set T to training engine 182 (e.g., of server machine 180) for training surrogate model 190.

Server machine 180 includes a training engine 182, a validation engine 184, a selection engine 186, and/or a testing engine 188. An engine can refer to hardware (e.g., circuitry, dedicated logic, programmable logic, microcode, processing device, etc.), software (such as instructions run on a processing device, a general purpose computer system, or a dedicated machine), firmware, microcode, or a combination thereof. Training engine 182 can be capable of training a machine learning model 190. The machine learning model 190 can refer to the model artifact that is created by the training engine 182 using the training data that includes training inputs and corresponding target outputs (correct answers for respective training inputs). The training engine 182 can find patterns in the training data that map the training input to the target output (the answer to be predicted), and provide the machine learning model 190 that captures these patterns. In some embodiments, the machine learning model 190 uses one or more of support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network, a recurrent neural network, a convolutional neural network, etc.), clustering techniques (e.g., hierarchical clustering techniques), association techniques (e.g., apriori techniques), classification techniques (e.g., decision trees, random forest techniques, etc.), a variational recurrent auto-encoder, etc. It should be noted that although some embodiments of the present disclosure describe model 190 as a machine learning model, such embodiments can be applied to any type of AI model, non-AI based model (e.g., a statistical model, a physical model, etc.), and/or a hybrid model (e.g., implementing AI techniques and non-AI techniques).

The validation engine 184 can be capable of validating a trained machine learning model 190 using a corresponding set of features of a validation set from training set generator 172. The validation engine 184 can determine an accuracy of each of the trained machine learning models 190 based on the corresponding sets of features of the validation set. The validation engine 184 can discard a trained machine learning model 190 that has an accuracy that does not meet a threshold accuracy. In some embodiments, the selection engine 185 can be capable of selecting a trained machine learning model 190 that has an accuracy that meets a threshold accuracy. In some embodiments, the selection engine 185 can be capable of selecting the trained machine learning model 190 that has the highest accuracy of the trained machine learning models 190.

The testing engine 186 can be capable of testing a trained machine learning model 190 using a corresponding set of features of a testing set from data set generator 172. For example, a first trained machine learning model 190 that was trained using a first set of features of the training set can be tested using the first set of features of the testing set. The testing engine 186 can determine a trained machine learning model 190 that has the highest accuracy of all of the trained machine learning models based on the testing sets.

Predictive server 112 includes a predictive component 114 that is capable of data as an input to a trained model 190 and obtaining one or more outputs of the trained model 190. As illustrated above, predictive component 114 can additionally or alternatively be a component of computing system 150. Predictive component 114 can provide process data for a process that is to be performed using manufacturing equipment 124 as an input to surrogate model 190 and obtain one or more outputs of the surrogate model 190, which can indicate a predicted simulated response of the digital twin based on the given process data.

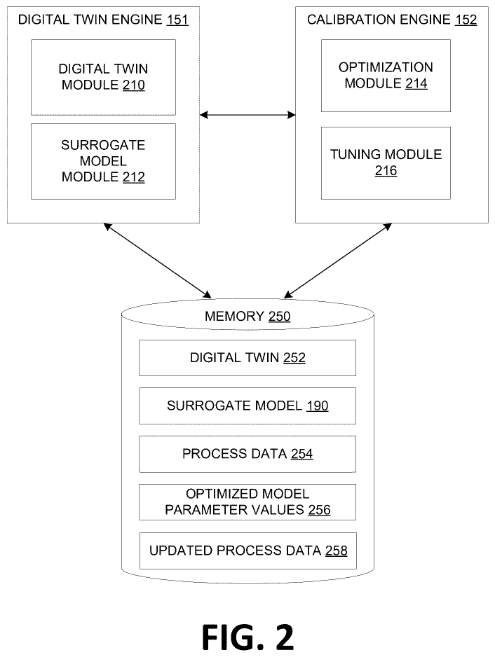

As described above, the digital twin, and therefore the surrogate model 190, are trained using data that is collected across multiple manufacturing equipment 124 (e.g., sometimes at various manufacturing systems). However, as there can be variations across processes and across manufacturing equipment 124, the predicted simulated responses obtained as an output of surrogate model 190 may not accurately reflect an actual response of the actual manufacturing equipment 124 that performs the actual process. Calibration engine 152 of computing system 150 can calibrate surrogate model 190 by determining optimized model parameters for surrogate model 190 based on a difference between the predicted simulated response for a process and an actual response of the process using manufacturing equipment 124. Details regarding calibration engine 152 are provided with respect to FIGS. 2-5 below.

The client device 120, manufacturing equipment 124, metrology equipment 128, predictive server 112, data store 140, server machine 170, and server machine 180 can be coupled to each other via a network 130. In some embodiments, network 130 is a public network that provides client device 120 with access to predictive server 112, data store 140, and other publicly available computing devices. In some embodiments, network 130 is a private network that provides client device 120 access to manufacturing equipment 124, metrology equipment 128, data store 140, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof.

It should be noted that in some other implementations, the functions of server machines 170 and 180, as well as predictive server 112, can be provided by a fewer number of machines. For example, in some embodiments, server machines 170 and 180 can be integrated into a single machine, while in some other or similar embodiments, server machines 170 and 180, as well as predictive server 112, can be integrated into a single machine.

In general, functions described in one implementation as being performed by server machine 170, server machine 180, and/or predictive server 112 can also be performed on client device 120. In addition, the functionality attributed to a particular component can be performed by different or multiple components operating together.

In embodiments, a “user” can be represented as a single individual. However, other embodiments of the disclosure encompass a “user” being an entity controlled by a plurality of users and/or an automated source. For example, a set of individual users federated as a group of administrators can be considered a “user.”

FIG. 2 is a block diagram of an example digital twin engine 151 and an example calibration engine 152, according to aspects of the present disclosure. As described above, digital twin engine 151 can build or otherwise obtain a digital twin that represents a virtual representation of manufacturing equipment 124 and/or initiate a training process for a surrogate model 190. Calibration engine 152 can calibrate the surrogate model 190 to improve outputs of the surrogate model 190 so to match (or approximately match) an actual response of an actual process performed using manufacturing equipment 124. As illustrated by FIG. 2, digital twin engine 151 includes a digital twin module 210 and/or a surrogate model module 212, and calibration engine 152 can include an optimization module 214 and/or a tuning module 216. Details regarding calibrating the surrogate model 190 for the digital twin are provided below with respect to FIGS. 2-5. In some embodiments, digital twin engine 151 and/or calibration engine 152 can be connected to memory 250 (e.g., via network 130). Memory 250 can include one or more portions of data store 140, in some embodiments. In other or similar embodiments, memory 250 can include any memory of or accessible to a component of system 100.

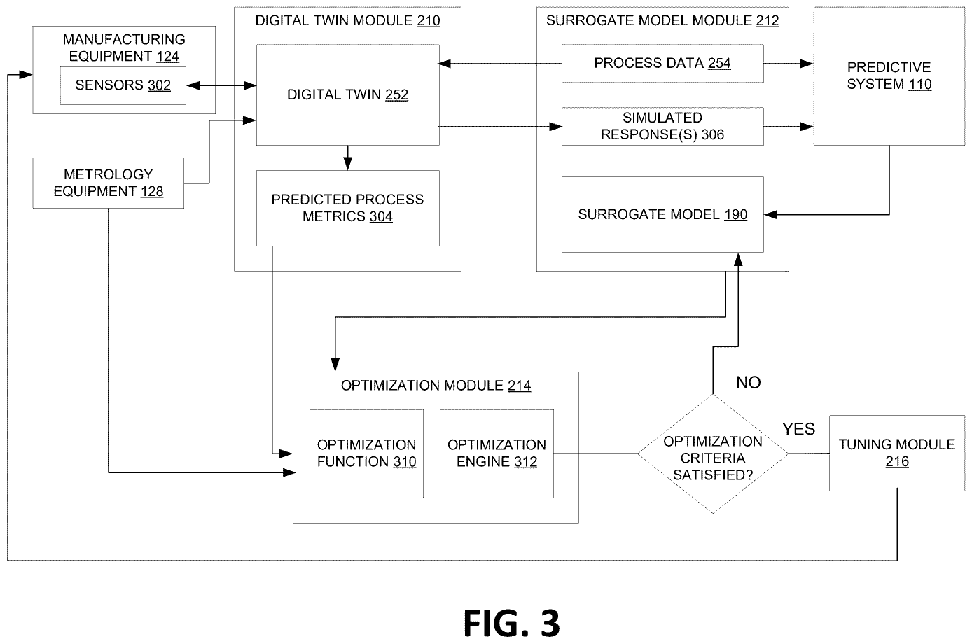

FIG. 3 is block diagram depicting an example of calibrating an on-tool digital twin model, according to aspects of the present disclosure. In some embodiments, the digital twin can include digital twin 252 that is built or otherwise obtained by digital twin module 210 of digital twin engine 151, in accordance with embodiments described herein. For example, as illustrated by FIG. 3, digital twin module 210 can build or otherwise obtain digital twin 252 based on data associated with an actual process performed using manufacturing equipment 124. In some embodiments, the data can be sensor data that is collected by one or more sensors 320 of or associated with manufacturing equipment 124. In other or similar embodiments, the data can include metrology data measured by metrology equipment 128 for one or more substrate before, during, and/or after performance of the actual process. As described above, the data used to build or obtain digital twin 252 can include additional or alternative data, in some embodiments. As described above, digital twin 252 can provide a simulated response of a simulated process performed using simulated equipment. Such simulated response may be reflected as a predicted process metric 504.

Surrogate model module 212 of digital twin module 210 may train (or initiate training of) surrogate model 190, in accordance with embodiments described herein. In some embodiments, surrogate model module 212 can identify process data 254 for a substrate process (e.g., from memory 250), which can include one or more parameters or settings associated with a process recipe for the substrate process. In some embodiments, process data 254 can additionally or alternatively include DOE data, which varies process conditions and/or hyperparameters for the digital twin module 210 and/or the surrogate model 212. Surrogate model module 212 can provide the process recipe as an input to the digital twin 252 and obtain a simulated chamber response 308 of digital twin 252 based on the provided process parameters. Predictive system 110 can train surrogate model 190 based on the process data 254 and/or the obtained simulated chamber response 308, as described above. Initially, process data 254 used for training surrogate model 190 can include design of experiments (DOE) data, which includes data that is specifically selected or identified for training the surrogate model 190 to predict simulated responses for process data associated with a wide range of substrate process types. However, as will be seen below, calibration engine 152 can obtain optimized model parameter values 256 for surrogate model 190 based on actual conditions of actual equipment 124 of a manufacturing system and can retrain or otherwise update surrogate model 190 to improve predictions of simulated response for process data associated with processes performed using the actual equipment 124. Such retrained or updated surrogate model 190 reflects or otherwise serves as an “on-tool digital twin” for such manufacturing system, as described herein.

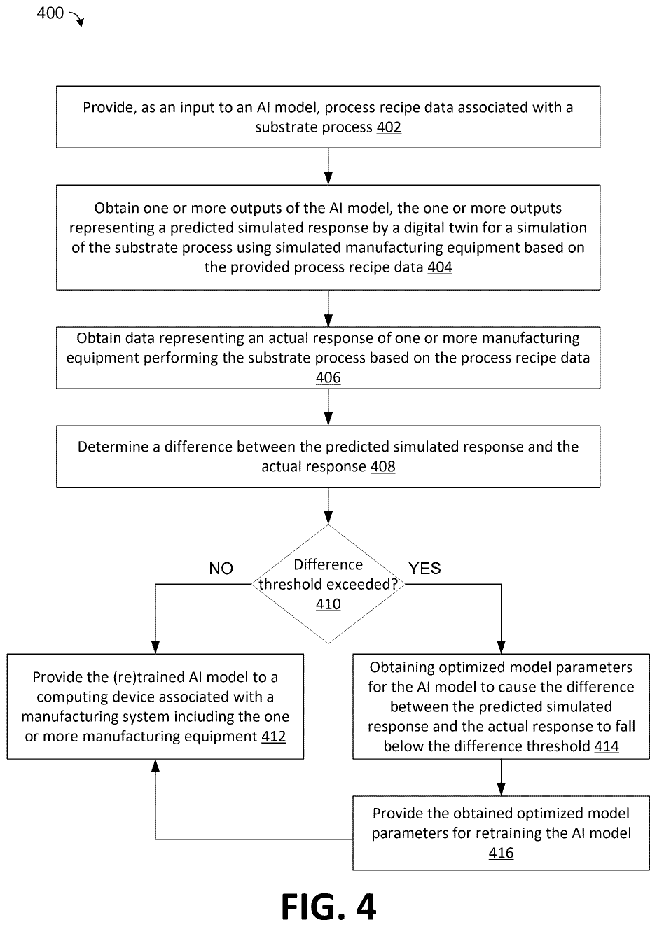

FIG. 4 is a flow chart of an example method 400 for calibrating on-tool digital twin models, according to aspects of the present disclosure. Method 400 is performed by processing logic that can include hardware (circuitry, dedicated logic, etc.), software (such as is run on a general-purpose computer system or a dedicated machine), firmware, or some combination thereof. In one implementation, method 400 can be performed by a computer system, such as computer system architecture 100 of FIG. 1. In other or similar implementations, one or more operations of method 400 can be performed by one or more other machines not depicted in the figures. In some aspects, one or more operations of method 300 can be performed by calibration engine 152.

For simplicity of explanation, method 400 is depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 402, processing logic provides, as an input to an AI model, process recipe data associated with a substrate process. The AI model may be trained to predict simulated responses by a digital twin simulating substrate processes using one or more simulated manufacturing equipment. The AI model can include surrogate model 190 that is trained based on process data 254 and/or obtained simulated responses 306 of digital twin 252, as described above. In some embodiments, the process recipe data can be included in process data 254 (e.g., at memory 250) for a substrate process to be performed using manufacturing equipment 124 at a manufacturing system. At block 404, processing logic obtains one or more outputs of the AI model. The one or more outputs can represent a predicted simulated response 306 by digital twin 252 for a simulation of the substrate process using simulated manufacturing equipment based on the provided process recipe data.

At block 406, processing logic obtains data representing an actual response of one or more manufacturing equipment performing the substrate process based on the process recipe data. In some embodiments, a system controller for the manufacturing system including manufacturing equipment 124 can initiate performance of the substrate process using manufacturing equipment 124 according to the process recipe of process data 254. In an illustrative example, an engineer or operator of the manufacturing system can provide a request for the system controller to initiate the performance of the substrate process by engaging with one or more user interface (UI) elements of a UI (e.g., a process dashboard) of client device 120. Before, during, and/or after the performance of the substrate process, sensors 302 of manufacturing equipment 124 can collect sensor data indicating a condition of an environment of the manufacturing equipment 124 based on the substrate process, in some embodiments. In additional or alternative embodiments, metrology equipment 128 can generate metrology data indicating characteristics of one or more substrates subject to the substrate process (e.g., before, during, and/or after the process). Such sensor data and/or metrology data can be stored at memory 250 as process data 254 (e.g., with a mapping to the process recipe). Optimization module 214 can determine the actual result of the substrate process performed using the manufacturing equipment 124 based on the process data 254 for the performed substrate process. In some embodiments, the actual result of the substrate process can be reflected by or otherwise include one or more values of the collected sensor data and/or one or more values of the metrology data.

At block 408, processing logic determines a difference between the predicted simulated response and the actual response. Optimization module 214 can determine the difference between the predicted simulated response and the actual response based on a comparison of the predicted simulated response and the actual response. In some embodiments, the determined difference can be reflected as a numerical difference between values of the collected sensor data and predicted sensor values included in the predicted simulated response(s) 306 of surrogate model 190. For example, a temperature sensor of manufacturing equipment 124 can measure a temperature of approximately 300 degree Celsius (° C.) in the process chamber during a performance of the substrate process, while the predicted temperature value of the predicted simulated response 306 for the substrate process is approximately 320° C. Accordingly, optimization module 214 can determine that the difference between the predicted temperature value and the measured temperature value is approximately 20° C. In another example, an etch rate measured for a substrate subject to the substrate process in the process chamber can be approximately 400 nanometers per minute (nm/min), while the predicted etch rate of the predicted simulated response 306 of the substrate process is approximately 390 nm/min. Accordingly, optimization module 214 can determine that the difference between the measured etch rate and the predicted etch rate is 10 nm/min. It should be noted that the difference between the predicted simulated response and the actual response can be determined according to other techniques.

In some embodiments, the difference between the predicted simulated response and the actual response may be determined based on an output of one or more optimization functions 310. An optimization function 310 refers to a function that quantifies the difference between a predicted output of an AI model and an actual target output. In some embodiments, the optimization function can include a cost function. Examples of an optimization function 310 include, for example, a mean squared error (MSE) cost function, a cross-entropy loss cross function, a mean absolute error (MAE) cost function, a Huber loss cost function, a R-Squared (R²) cost function, and so forth. In some embodiments, optimizer module 212 can identify a cost function 310 that is specifically associated with a type of surrogate model 190. For example, as described above, surrogate model 190 can include a regression model (e.g., a Gaussian regression model). Optimization module 212 can identify a MSE cost function, a MAE cost function, a Huber loss cost function, a R² cost function, etc. as associated with surrogate model 190 (e.g., based on information provided to system 100 by a developer or operator and/or otherwise obtained using data of public or private resources). In some embodiments, optimization module 214 can provide the predicted simulation response and the actual response as an input to the cost function 310 and obtain one or more outputs indicating the difference between the predicted simulated response and the actual response. The difference indicated by the output(s) of the cost function can reflect a calculated error of the predictions by model 190 and the actual target value, in some embodiments.

At block 410, processing logic determines whether the difference between the predicted simulated response and the actual response exceeds a difference threshold. In some embodiments, the difference threshold can be provided by an engineer or operator of the manufacturing system and/or system 100. In other or similar embodiments, the difference threshold can be calculated or otherwise determined based on testing data and/or experimental data associated the manufacturing system. Upon a determination that the difference between the predicted simulated response and the actual response does not exceed a difference threshold, method 400 proceeds to block 412. At block 412, processing logic provides the trained AI model to a computing device associated with a manufacturing system including the one or more manufacturing equipment. In some embodiments, optimization module 214 can reside at a set of computing devices that are remote from the computing device associated with the system controller of the manufacturing system. In such embodiments, optimization module 214 may identify the computing device associated with the system controller and transmit the trained surrogate model 190 to the identified computing device (e.g., via a network, via a bus, etc.). In other or similar embodiments, optimization module 214 can reside at a computing device that includes the system controller and/or is otherwise accessible to the system controller. In such embodiments, optimization module 214 may transmit a signal to the system controller indicating that the trained surrogate model 190 is available to be accessed for substrate processes, as described herein.

Upon a determination that difference between the predicted simulated response and the actual response exceeds a difference threshold, method 400 proceeds to block 414. At block 414, processing logic obtains optimized model parameters for the AI model to cause the difference between the predicted simulated response and the actual response to fall below the difference threshold. In some embodiments, optimization module 214 can provide the predicted simulated response 306 for the substrate process and data (e.g., sensor data, metrology data, etc.) representing the actual response as input to an optimization engine 312. The optimization engine 312 can perform one or more operations to identify a global optimum value of the optimization function 310 (e.g., a global minimum value). In some embodiments, optimization engine 312 include or otherwise correspond to a Bayesian optimization model that implements Bayesian interference techniques to model the optimization function 310. Bayesian optimization can involve building a probabilistic model of the optimization function 310, which represents the behavior of the optimization function 310 across the entire input space.

In some embodiments, the optimization engine 312 can obtain initial sampling data for the predicted simulated response 308 by values for one or more model parameters of surrogate model 190 that correspond to the predicted simulated response 308. A model parameter can correspond to a predicted simulated response 308 if a value of the model parameter impacted the predicted simulated response 308, based on the given input to the surrogate model 190. Optimization engine 312 can provide the sampling data as an input to an acquisition function that determines additional sampling data to be subsequently evaluated using the optimization function 310. Such acquisition function can include an expected improvement function, an upper confidence bound function, a probability of improvement function, or other such type of optimization functions. In some embodiments, the additional sampling data can indicate updated values for the one or more model parameters, for exploration by the optimization function 310. Optimization engine 312 can update the one or more model parameters of the surrogate model 190 to match the updated values and can apply the one or more model parameters to the process data 254 to obtain an updated predicted simulated response 306. Optimization engine 312 can determine a difference between the updated predicted simulated response 306 and the actual response and determine whether one or more optimization criteria are satisfied based on the determined difference. In some embodiments, optimization engine 312 can determined the difference based on one or more outputs of the optimization function 312, as described above. The one or more optimization criteria can be satisfied if a degree of convergence of the predicted simulated responses 306 toward the actual response meets or exceeds a threshold degree of convergence, in some embodiments. In other or similar embodiments, the one or more optimization criteria can be satisfied if a threshold number of updated predicted simulated responses 306 have been obtained and/or a threshold amount of computing resources (e.g., processing cycles) have been consumed to obtain the updated predicted simulated responses 306.

Upon determining that the optimization criteria are not satisfied, optimization engine 312 can provide the additional sampling data as an input to the acquisition function and can obtain updated sampling data based on one or more outputs of the acquisition function. Optimization engine 312 can continue the above described operations (e.g., obtaining updated simulated response(s) 306, upon determining that the optimization criteria are not satisfied, obtaining updated sampling data based on one or more outputs of the acquisition function, etc.) until the one or more optimization criteria are satisfied. The values of the model parameters that caused the optimization data to be satisfied are referred to as optimized model parameter values 256.

At block 416, processing logic provides the obtained optimized parameters for retraining the AI model. Optimization model 214 can provide the optimized model parameter values 256 to tuning module 216. Tuning module 216 can identify one or more hyperparameters of the surrogate model 190 that correspond to the optimized model parameter values 256 and can update the hyperparameters to match the optimized model parameter values 256. Upon updating the hyperparameters to match the optimized model parameter values 256, the surrogate model 190 is a retrained AI model 190 that is tuned to predict the simulated response(s) 306 for manufacturing equipment 124 of the manufacturing system.

Upon completion of retraining the AI model, method 400 proceeds to block 412, where processing logic provides the retrained AI model to the computing device associated with a manufacturing system including the one or more manufacturing equipment. Optimization module 214 can provide the retrained AI model (e.g., retrained surrogate model 190) to the computing device associated the manufacturing system, as described above.

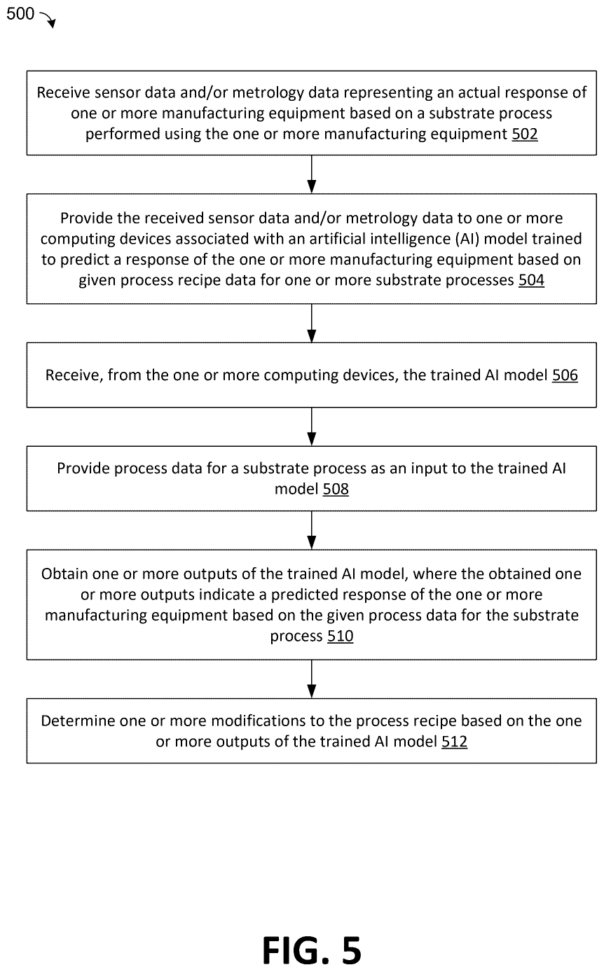

FIG. 5 is a flow chart of another example method 500 for calibrating on-tool digital twin models, according to aspects of the present disclosure. Method 500 is performed by processing logic that can include hardware (circuitry, dedicated logic, etc.), software (such as is run on a general-purpose computer system or a dedicated machine), firmware, or some combination thereof. In one implementation, method 500 can be performed by a computer system, such as computer system architecture 100 of FIG. 1. In other or similar implementations, one or more operations of method 500 can be performed by one or more other machines not depicted in the figures. In some aspects, one or more operations of method 500 can be performed by a computing device of a manufacturing system that includes manufacturing equipment 124. For example, one or more operations of method 500 can be performed by a client device 120 of the manufacturing system or a computing device associated with a system controller of the manufacturing system.

For simplicity of explanation, method 500 is depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 502, processing logic receives sensor data representing an actual response of one or more manufacturing equipment based on a substrate process performed using the one or more manufacturing equipment. The manufacturing equipment can include manufacturing equipment 124 of the manufacturing system and the sensor data may be collected or otherwise obtained by sensors 302, as described above. In some embodiments, the metrology data can be collected by metrology equipment 128 for a substrate (or a lot of substrates) subject to the actual process, as described above.

At block 504, processing logic provides the received sensor data and/or metrology data to one or more computing devices associated an AI model trained to predict a response of the one or more manufacturing equipment based on given process recipe data for one or more substrate processes. In some embodiments, the one or more computing devices can be included at computing system 150 and/or predictive system 110. The AI model can be surrogate model 190 that is trained to predict the simulated response of the substrate process, as described above. In some embodiments, processing logic can provide the received sensor data and/or metrology data via network 130.

At block 506, processing logic receives, from the one or more computing devices, the trained AI model. Calibration engine 152 can train or otherwise tune the surrogate model 190 to predict the response of the substrate process(es) performed using manufacturing equipment 124, in accordance with embodiments described above. Upon completion of the training/tuning of the surrogate model 190, calibration engine 152 can provide processing logic with access to the trained/tuned surrogate model 190. For example, calibration engine 152 can transmit model 190 to the computing device of the manufacturing system 100 via network 130. In another example, calibration engine 152 can transmit a notification to the computing device indicating that the trained/tuned model 190 is available to the system controller of the manufacturing system.

At block 508, processing logic provides process for a substrate process as an input to the trained AI model. The process data 254 can include a process recipe for the substrate process, in some embodiments. The substrate process can include a future substrate process or a prior substrate process, in some embodiments. At block 510, processing logic obtains one or more outputs of the trained AI model, where the obtained one or more outputs indicate a predicted response of the manufacturing equipment 124 based on the given process data for the substrate process.

At block 512, processing logic determines one or more modifications to the process recipe based on one or more outputs of the AI model. In some embodiments, processing logic may determine the one or more modifications to the process recipe by determining a difference between the predicted response of the manufacturing equipment 124 and a target response of the manufacturing equipment. For example, the predicted response can indicate that a temperature of the manufacturing equipment 124 during the substrate process is 295° C. and a target temperature of the manufacturing equipment 124 is 300° C. Processing logic can determine one or more updated settings of the process recipe to counteract the 5° C. difference between the temperature of the predicted response and the target temperature. In some embodiments, processing logic can store the updated settings at memory 250 as updated process data.

As described herein, in some embodiments, outputs of the trained/tuned surrogate model 190 can be used for process control (e.g., run-to-run process control) at the manufacturing system, in some embodiments. In other or similar embodiments, outputs of the trained/tuned surrogate model can be used for other purposes, such as drift detection, process recipe optimization, and so forth.

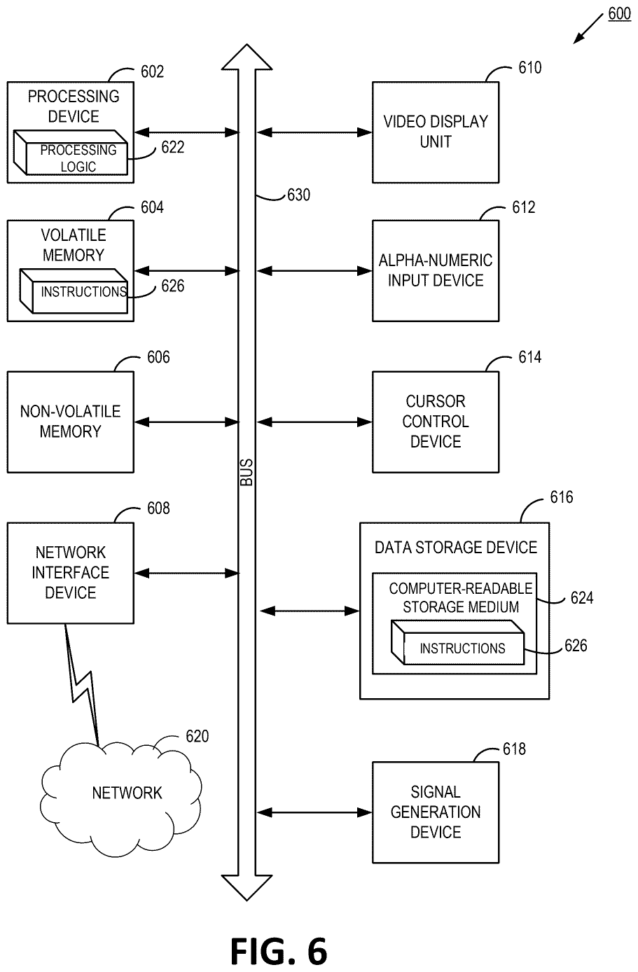

FIG. 6 depicts a block diagram of an illustrative computer system 600 operating in accordance with one or more aspects of the present disclosure. In alternative embodiments, the machine can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 600 can correspond to predictive server 112 of FIG. 1 or another processing device of system 100.

The example computing device 600 includes a processing device 602, a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 628), which communicate with each other via a bus 608.

Processing device 602 can represent one or more general-purpose processors such as a microprocessor, central processing unit, or the like. More particularly, the processing device 602 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. Processing device 602 can also be or include a system on a chip (SoC), programmable logic controller (PLC), or other type of processing device. Processing device 602 is configured to execute the processing logic for performing operations and steps discussed herein.

The computing device 600 can further include a network interface device 622 for communicating with a network 664. The computing device 600 also can include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 620 (e.g., a speaker).

The data storage device 628 can include a machine-readable storage medium (or more specifically a non-transitory computer-readable storage medium) 624 on which is stored one or more sets of instructions 626 embodying any one or more of the methodologies or functions described herein. Wherein a non-transitory storage medium refers to a storage medium other than a carrier wave. The instructions 626 can also reside, completely or at least partially, within the main memory 604 and/or within the processing device 602 during execution thereof by the computer device 600, the main memory 604 and the processing device 602 also constituting computer-readable storage media.

The computer-readable storage medium 624 can also be used to store model 190 and data used to train model 190. The computer readable storage medium 624 can also store a software library containing methods that call model 190. While the computer-readable storage medium 624 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
providing, as an input to an artificial intelligence (AI) model, process recipe data associated with a substrate process, wherein the AI model is trained to predict simulated responses by a digital twin simulating substrate processes using one or more simulated manufacturing equipment;
obtaining one or more outputs of the AI model, wherein the one or more outputs represent a predicted simulated response by the digital twin for a simulation of the substrate process using the one or more simulated manufacturing equipment based on the provided process recipe data;
obtaining data representing an actual response of one or more manufacturing equipment performing the substrate process based on the process recipe data;
responsive to determining that a difference between the predicted simulated response and the actual response exceeds a difference threshold, obtaining optimized values of one or more model parameters for the AI model, wherein the optimized values of the one or more model parameters cause the difference between the predicted simulated response and the actual response to fall below the difference threshold; and
providing the optimized values of the one or more model parameters for retraining the AI model.

2. The method of claim 1, further comprising:
responsive to determining that one or more retraining criteria associated with the AI model are satisfied, providing the retrained AI model to a computing device associated with a manufacturing system that includes the one or more manufacturing equipment.

3. The method of claim 1, further comprising:
providing the one or more outputs of the AI model indicating the predicted simulated response and the obtained data representing the actual response as an input to an optimization engine, wherein the optimization engine performs one or more operations to:
determine an optimization function associated with the AI model, and
identify the optimized values of the one or more model parameters based on sampling data provided as input to the determined optimization function,
wherein the optimized values of the one or more model parameters are obtained based on one or more outputs of the optimization engine.

4. The method of claim 3, wherein the optimization engine comprises a Bayesian optimization model, and wherein the optimization function comprises a cost function.

5. The method of claim 1, wherein,
the predicted simulated response comprises at least one of:
a predicted simulated condition of the one or more simulated manufacturing equipment based on the simulation of the substrate process, or
a predicted simulated characteristics of one or more simulated substrates subject to the simulated substrate process, and
the actual response comprises at least one of:
an actual condition of the one or more manufacturing equipment performing the substrate process based on sensor data collected by one or more sensors of the one or more manufacturing equipment, or
actual characteristics of one or more substrates subject to the substrate processed performed using the one or more manufacturing equipment based on metrology data collected for the one or more substrates.

6. The method of claim 1, wherein providing the optimized model parameters for retraining the AI model comprises:
identifying one or more hyperparameters of the AI model corresponding to the model parameters associated with the optimized values; and
updating current values of the identified one or more hyperparameters to match the optimized values.

7. The method of claim 1, wherein the AI model is trained using a training data set comprising one or more training inputs and, for each of the one or more training inputs, a target output, wherein a training input comprises process recipe data associated with a historical substrate process performed using one or more additional manufacturing equipment and the target output comprises the actual response of the one or more additional manufacturing equipment based on a performance of the historical substrate process according to a process recipe of the process recipe data.

8. The method of claim 1, wherein the AI model is a Gaussian Process regression model.

9. A system comprising:
a memory; and
a set of one or more processing devices coupled to the memory, wherein the set of one or more processing devices is to:
provide, as an input to an artificial intelligence (AI) model, process recipe data associated with a substrate process, wherein the AI model is trained to predict simulated responses by a digital twin simulating substrate processes using one or more simulated manufacturing equipment;
obtain one or more outputs of the AI model, wherein the one or more outputs represent a predicted simulated response by the digital twin for a simulation of the substrate process using the one or more simulated manufacturing equipment based on the provided process recipe data;
obtain data representing an actual response of one or more manufacturing equipment performing the substrate process based on the process recipe data;
responsive to determining that a difference between the predicted simulated response and the actual response exceeds a difference threshold, obtain optimized values of one or more model parameters for the AI model, wherein the optimized values of the one or more model parameters cause the difference between the predicted simulated response and the actual response to fall below the difference threshold; and
provide the optimized values of the one or more model parameters for retraining the AI model.

10. The system of claim 9, wherein the set of one or more processing devices is further to:
responsive to determining that one or more retraining criteria associated with the AI model are satisfied, provide the retrained AI model to a computing device associated with a manufacturing system that includes the one or more manufacturing equipment.

11. The system of claim 9, wherein the set of one or more processing devices is further to:
provide the one or more outputs of the AI model indicating the predicted simulated response and the obtained data representing the actual response as an input to an optimization engine, wherein the optimization engine performs one or more operations to:
determine an optimization function associated with the AI model, and
identify the optimized values of the one or more model parameters based on sampling data provided as input to the determined optimization function,
wherein the optimized values of the one or more model parameters are obtained based on one or more outputs of the optimization engine.

12. The system of claim 11, wherein the optimization engine comprises a Bayesian optimization model, and wherein the optimization function comprises a cost function.

13. The system of claim 9, wherein,
the predicted simulated response comprises at least one of:
a predicted simulated condition of the one or more simulated manufacturing equipment based on the simulation of the substrate process, or
a predicted simulated characteristics of one or more simulated substrates subject to the simulated substrate process, and
the actual response comprises at least one of:
an actual condition of the one or more manufacturing equipment performing the substrate process based on sensor data collected by one or more sensors of the one or more manufacturing equipment, or
actual characteristics of one or more substrates subject to the substrate processed performed using the one or more manufacturing equipment based on metrology data collected for the one or more substrates.

14. The system of claim 9, wherein to provide the optimized model parameters for retraining the AI model, the set of one or more processing devices is further to:
identify one or more hyperparameters of the AI model corresponding to the model parameters associated with the optimized values; and
update current values of the identified one or more hyperparameters to match the optimized values.

15. The system of claim 9, wherein the AI model is trained using a training data set comprising one or more training inputs and, for each of the one or more training inputs, a target output, wherein a training input comprises process recipe data associated with a historical substrate process performed using one or more additional manufacturing equipment and the target output comprises the actual response of the one or more additional manufacturing equipment based on a performance of the historical substrate process according to a process recipe of the process recipe data.

16. A non-transitory computer readable medium comprising instructions that, when executed by a set of one or more processing devices, cause the set of one or more processing devices to:
provide, as an input to an artificial intelligence (AI) model, process recipe data associated with a substrate process, wherein the AI model is trained to predict simulated responses by a digital twin simulating substrate processes using one or more simulated manufacturing equipment;
obtain one or more outputs of the AI model, wherein the one or more outputs represent a predicted simulated response by the digital twin for a simulation of the substrate process using the one or more simulated manufacturing equipment based on the provided process recipe data;
obtain data representing an actual response of one or more manufacturing equipment performing the substrate process based on the process recipe data;
responsive to determining that a difference between the predicted simulated response and the actual response exceeds a difference threshold, obtain optimized values of one or more model parameters for the AI model, wherein the optimized values of the one or more model parameters cause the difference between the predicted simulated response and the actual response to fall below the difference threshold; and
provide the optimized values of the one or more model parameters for retraining the AI model.

17. The non-transitory computer readable medium of claim 16, wherein the set of one or more processing devices is further to:
responsive to determining that one or more retraining criteria associated with the AI model are satisfied, provide the retrained AI model to a computing device associated with a manufacturing system that includes the one or more manufacturing equipment.

18. The non-transitory computer readable medium of claim 16, wherein the set of one or more processing devices is further to:
provide the one or more outputs of the AI model indicating the predicted simulated response and the obtained data representing the actual response as an input to an optimization engine, wherein the optimization engine performs one or more operations to:
determine an optimization function associated with the AI model, and
identify the optimized values of the one or more model parameters based on sampling data provided as input to the determined optimization function,
wherein the optimized values of the one or more model parameters are obtained based on one or more outputs of the optimization engine.

19. The non-transitory computer readable medium of claim 18, wherein the optimization engine comprises a Bayesian optimization model, and wherein the optimization function comprises a cost function.

20. The non-transitory computer readable medium of claim 16, wherein,
the predicted simulated response comprises at least one of:
a predicted simulated condition of the one or more simulated manufacturing equipment based on the simulation of the substrate process, or
a predicted simulated characteristics of one or more simulated substrates subject to the simulated substrate process, and
the actual response comprises at least one of:
an actual condition of the one or more manufacturing equipment performing the substrate process based on sensor data collected by one or more sensors of the one or more manufacturing equipment, or
actual characteristics of one or more substrates subject to the substrate processed performed using the one or more manufacturing equipment based on metrology data collected for the one or more substrates.
